(19) United States
(12) Patent Application Publication
(10) Pub. No.: US 2011/0044476 A1
(43) Pub. Date: Feb. 24, 2011

(54) SYSTEM TO GENERATE ELECTRICAL SIGNALS FOR A LOUDSPEAKER

(75) Inventors: Gregory B. BURLINGAME, Woburn, MA (US); Stephen L. MARTIN, Peabody, MA (US); Jonathan R. WOOD, Sudbury, MA (US)

Correspondence Address: GROSSMAN, TUCKER, PERREAULT & PFLEGER, PLLC, 55 SOUTH COMMERICAL STREET, MANCHESTER, NH, 03101, US

(73) Assignee: EMO LABS, INC., Waltham, MA (US)

(21) Appl. No.: 12/857,231

(22) Filed: Aug. 16, 2010

Related U.S. Application Data
(60) Provisional application No. 61/234,069, filed on Aug. 14, 2009.

(51) Int. Cl. H03F 99/00; H04R 17/00

(52) U.S. Cl. 381/121; 381/190

(57) ABSTRACT

The present disclosure describes an apparatus and a system for generating electrical signals for a loudspeaker. The loudspeaker may include one or more piezoelectric actuators configured to deflect a diaphragm of the loudspeaker in response to an input signal. The apparatus may be configured to receive the input signal and to drive the piezoelectric actuators to deflect the diaphragm based on the received input signal.

### CROSS REFERENCE TO RELATED APPLICATIONS

This application claims the benefit of U.S. provisional patent application Ser. No. 61/234,069, filed Aug. 14, 2009, the entire disclosure of which is incorporated herein by reference.

### FIELD

The present disclosure relates to a system for generating electrical signals for a loudspeaker.

### BACKGROUND

Mechanical-to-acoustical transducers may have an actuator that may be coupled to an edge of a speaker membrane or diaphragm. The speaker membrane or diaphragm may then be anchored and spaced from the actuator. This may be understood as an edge-motion type loudspeaker. Such a system may provide a diaphragm-type speaker where a display may be viewed through the speaker. The actuators may be electromechanical, such as electromagnetic, piezoelectric or electrostatic. Piezoelectric actuators do not create a magnetic field that may interfere with a display image. Piezoelectric actuators may also be well suited to transform a high efficiency short linear travel of the piezoelectric motor into a high excursion, piston-equivalent diaphragm movement.

One example of mechanical-to-acoustical transducer including an actuator that may be coupled to an edge of a diaphragm material is recited in U.S. Pat. No. 7,038,356. The use of a support and actuator that was configured to be responsive to what was identified as surrounding conditions of, e.g., heat and/or humidity, is described in U.S. Publication No. 2006/0269087.

### SUMMARY

The present disclosure relates in one embodiment to an apparatus for use with an acoustic transducer including a piezoelectric actuator. The apparatus includes an error amplifier circuit configured to receive an input signal and a feedback signal and to provide an output based at least in part on the input signal and the feedback signal wherein the input signal is an audio frequency signal; an output stage coupled to the error amplifier circuit, the output stage configured to receive the output from the error amplifier circuit and to generate an output signal, based at least in part on the output from the error amplifier circuit wherein the output signal is configured to drive the piezoelectric actuator; and a charge sensing circuit configured to sense a charge associated with the piezoelectric actuator, wherein the feedback signal is based, at least in part, on the sensed charge.

The present disclosure relates in another embodiment to an acoustic transducer that converts a mechanical motion into acoustical energy. The acoustic transducer includes a diaphragm that is curved; at least one support on at least one portion of the diaphragm; at least one piezoelectric actuator operatively coupled to the diaphragm and spaced from the support, the actuator configured to move such that movement of the actuator produces corresponding movement of the diaphragm, the diaphragm movement being amplified with respect to the actuator movement; an error amplifier circuit configured to receive an input signal and a feedback signal and to provide an output based at least in part on the input signal and the feedback signal wherein the input signal is an audio frequency signal; an output stage coupled to the error amplifier circuit, the output stage configured to receive the output from the error amplifier circuit and to generate an output signal, based at least in part on the output from the error amplifier circuit wherein the output signal is configured to drive the piezoelectric actuator; and a charge sensing circuit configured to sense a charge associated with the piezoelectric actuator, wherein the feedback signal is based, at least in part, on the sensed charge.

In yet another embodiment, the present disclosure relates to a system. The system includes an acoustic transducer including a piezoelectric actuator; and an apparatus for driving the piezoelectric actuator. The apparatus includes an error amplifier circuit configured to receive an input signal and a feedback signal and to provide an output based at least in part on the input signal and the feedback signal wherein the input signal is an audio frequency signal; an output stage coupled to the error amplifier circuit, the output stage configured to receive the output from the error amplifier circuit and to generate an output signal, based at least in part on the output from the error amplifier circuit wherein the output signal is configured to drive the piezoelectric actuator; and a charge sensing circuit configured to sense a charge associated with the piezoelectric actuator, wherein the feedback signal is based, at least in part, on the sensed charge.

### BRIEF DESCRIPTION OF DRAWINGS

Features and advantages of the claimed subject matter will be apparent from the following detailed description of embodiments consistent therewith, which description should be considered with reference to the accompanying drawings, wherein:

FIGS. 1A and 1B illustrate functional block diagrams of systems configured to generate electrical signals for a loudspeaker consistent with the present disclosure; and

FIGS. 2A and 2B illustrate examples of systems to generate electrical signals for a loudspeaker consistent with the present disclosure;

FIG. 3A depicts an example of a circuit for generating a bias voltage for circuitry included in an output stage consistent with the present disclosure;

FIG. 3B depicts an example of a circuit for generating an offset voltage, e.g., for the system illustrated in FIG. 2B; and

FIG. 4 is an exemplary cross-sectional view illustrating diaphragm flexure. Although the following Detailed Description will proceed with reference being made to illustrative embodiments, many alternatives, modifications, and variations thereof will be apparent to those skilled in the art.

### DETAILED DESCRIPTION

Generally, this disclosure describes an apparatus and a system configured to generate electrical signals for driving a loudspeaker. In particular, a system consistent with the present disclosure is configured to provide a piezoelectric bias voltage and/or a drive signal for a piezoelectric actuator. The piezoelectric actuator may deflect with a force, in response to the drive signal, that may then deflect a speaker membrane or diaphragm of a loudspeaker. The system is configured to receive an input signal, e.g., an input audio frequency signal such as speech and/or music, and to generate the drive signal based on the input signal. For example, the force and deflection of the piezoelectric actuator may then be proportional to the input audio frequency signal. An audio frequency signal may include frequencies in the range of about 20 Hz to about 20,000 Hz.

The system is configured to receive an input signal that may be an audio frequency signal and to provide an output signal to drive one or more piezoelectric actuators, in proportion to the input signal. The system is configured to sense a charge associated with the piezoelectric actuators and to provide a feedback signal, based at least in part, on the sensed charge. The system is configured to adjust the output signal based at least in part on the input signal and the feedback signal. The system is configured to generate a relatively high piezoelectric bias voltage, e.g., in the range of about 100 VDC (Volts DC) to about 600 VDC, and a relatively high piezoelectric AC voltage, e.g., in the range of about 200 V peak to peak to about 1200 V peak to peak, for driving the piezoelectric actuator(s).

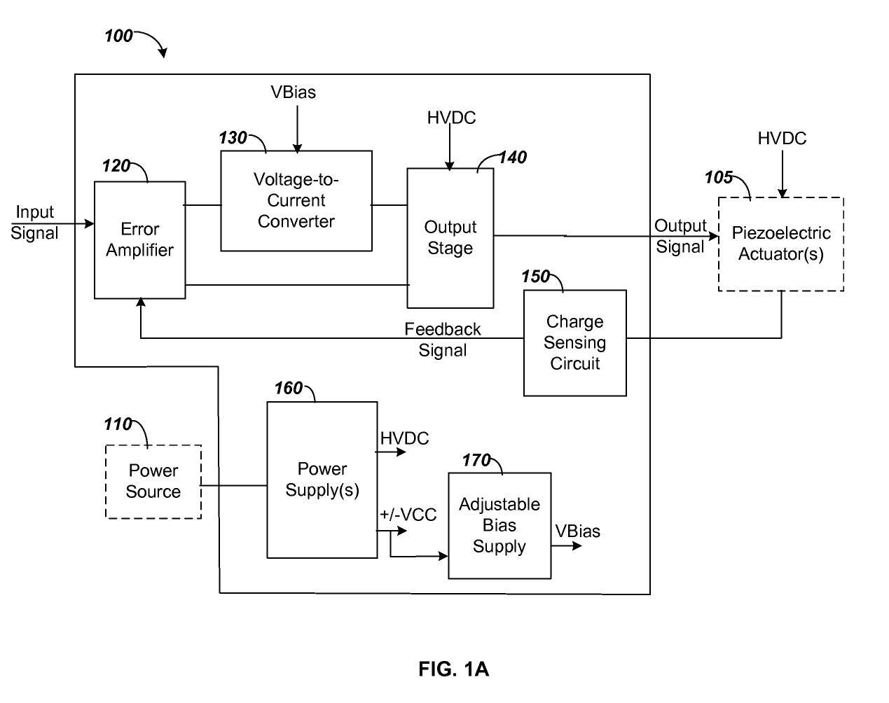

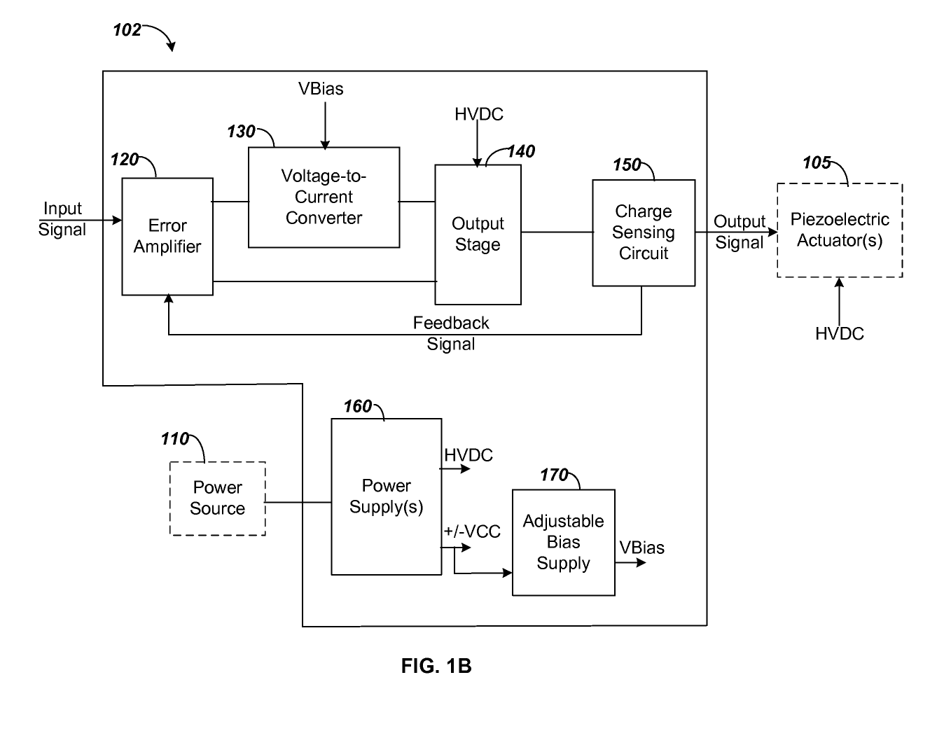

FIGS. 1A and 1B illustrate exemplary functional block diagrams of systems 100, 102 configured to generate electrical signals for a loudspeaker consistent with the present disclosure. The systems 100, 102 are configured to receive an input signal (Input Signal) and to generate an output signal (Output Signal) based, at least in part, on the input signal. The input signal may be an input audio frequency signal (e.g., frequencies in the range of about 20 Hz to about 20,000 Hz) that may include voice and/or music. The output signal may be an output voltage signal that may include a DC piezoelectric bias voltage and an AC signal proportional to the received input signal, configured to drive one or more piezoelectric actuator(s) 105. The systems 100, 102 are further configured to receive one or more inputs from a power source 110. The power source 110 may provide AC (alternating current) and/or positive and/or negative DC (direct current) supply voltage(s).

The systems 100, 102 may include an error amplifier circuit 120, a voltage to current converter 130, an output stage 140, a charge sensing circuit 150 and/or one or more adjustable bias supplies 170. The systems 100, 102 may include one or more power supply(s) 160. The power supply(s) 160 may include a transformer with one or more secondary windings and/or a plurality of transformers configured to provide one or more output voltages from an input voltage, as will be understood by one skilled in the art. As will be understood by one skilled in the art, the functionality of the power supply(s) 160 may be provided by circuitry, including but not limited to, DC/DC converter(s), linear regulator(s), charge pump(s) and/or voltage multiplier(s), etc. In system 100, the charge sensing circuit 150 may be coupled between the piezoelectric actuators 105 and the error amplifier circuit 120. In system 102, the charge sensing circuit 150 may be coupled between the output stage 140 and the piezoelectric actuators 105. The error amplifier circuit 120 is configured to receive the input signal and a feedback signal from the charge sensing circuit 150 and to provide an output based, at least in part, on the input signal and the feedback signal. The output of the error amplifier input 120 may be provided to the voltage to current converter 130 and to the output stage 140. The output of the error amplifier circuit 120 may represent a difference (i.e., error) between the input signal and the feedback signal. The feedback signal, as described herein, may represent a force and/or deflection of the piezoelectric transducer(s) 105. The error amplifier circuit 120 may then be configured to cause the system 100 to adjust the force and/or deflection of the piezoelectric actuator(s) 105 to correspond (e.g., match) to the input signal.

The voltage to current converter 130 is configured to receive the output from the error amplifier circuit 120 and to provide an output current based, at least in part, on the output from the error amplifier circuit 120. The voltage to current converter 130 is configured to receive a bias voltage, VBias. The bias voltage, VBias may be generated by a bias supply 170. The bias supply may receive a DC output voltage from, e.g., the power supply 160 and may then generate the bias voltage VBias. The output of the voltage to current converter 130 may then depend on the bias voltage VBias and the output from the error amplifier circuit 120. The output of the voltage to current converter 130 may then be provided to the output stage 140. The bias voltage, VBias, is configured to provide a bias voltage to circuitry (e.g., transistor(s)) in the output stage 140 in order to set a quiescent operating point (i.e., turn on) of the transistor(s). The voltage to current converter 130 is configured to drive a portion of the output stage 140 that is referenced to a voltage whose absolute value (e.g., 200 V) is greater than a supply voltage (e.g., +/−15 V) to the error amplifier circuit 120, as described herein.

The output stage 140 is configured to receive the output from the voltage to current converter 130 and the output from the error amplifier circuit 120. The output stage 140 is further configured to receive a high voltage DC input (HVDC) from the power supply(s) 160. In some embodiments, the HVDC may be floating with respect to ground. In other words, the HVDC may be applied across a positive node and a negative node of the output stage 140 and the HVDC potential may appear across the output stage 140. In these embodiments, a midpoint of the output stage 140 may be grounded, separate from the HVDC supply (i.e., the power supply 160). In these embodiments, the output signal may then appear on supply “rails”, e.g., HVDC+ and HVDC−, relative to a ground within the output stage 140, as described herein.

The output stage 140 may be a class A, class A/B, class B, class D, class G or class H amplifier stage. As will be understood by one skilled in the art, amplifier classes may correspond to the portion of an input signal cycle during which the amplifier conducts. The output stage 140 is configured to “drive” the piezoelectric actuator(s) 105, based at least in part on the input signal (Input Signal).

Piezoelectric actuators may generally be driven by relatively high voltages, e.g., on the order of hundreds of volts. Piezoelectric actuators are typically polarized, e.g., by applying a relatively high voltage across at least a portion of the actuator. The polarization may be necessary for proper operation of the actuator. Applying a relatively high voltage of opposite polarity across the portion of the actuator may result in depolarization of the piezeoelectric actuator. The actuator may then fail to deflect in response to a supplied voltage. In order to reduce the likelihood that a piezoelectric actuator may become depolarized, the system 100 is configured to provide both a piezoelectric bias voltage (DC) and a signal voltage (AC) to the piezoelectric actuator(s) 105. The piezoelectric bias voltage is configured to prevent depolarization and the signal voltage is configured to cause the piezoelectric actuator(s) 105 to deflect with a force, based at least in part on the input signal (Input Signal).

It may be appreciated that piezoelectric actuators are generally capacitive. Further, a force and/or deflection of a piezoelectric actuator may depend on a charge Q, associated with the piezoelectric actuator. It may be further appreciated that the charge, Q, contained in a capacitor is a function of voltage, V, across the capacitor and the capacitance, C, of the capacitor. In an ideal capacitor, Q=C*V, and C is a constant. Accordingly, in an ideal capacitor, with constant (known) capacitance, C, the charge, Q, in the capacitor may be determined by measuring the voltage, V, across the capacitor. In other words, the voltage, V, is proportional to the charge Q. In a piezoelectric actuator (and in piezoelectric devices in general), the capacitance may vary with voltage. Accordingly, a measured voltage may not be proportional to charge in the piezoelectric actuator. It may therefore be desirable to determine the charge associated with the piezoelectric actuator more directly.

Charge sensing circuit 150 is configured to sense and/or measure a charge associated with the piezoelectric actuator(s) 105 and to provide a feedback signal, representative of the detected charge to the error amplifier circuit 120. The error amplifier circuit 120 may then cause the system to adjust the output signal to the piezoelectric actuator(s) 105 so that the piezoelectric actuators deflect with a force. The force and/or deflection may then be proportional to the input signal, Input Signal.

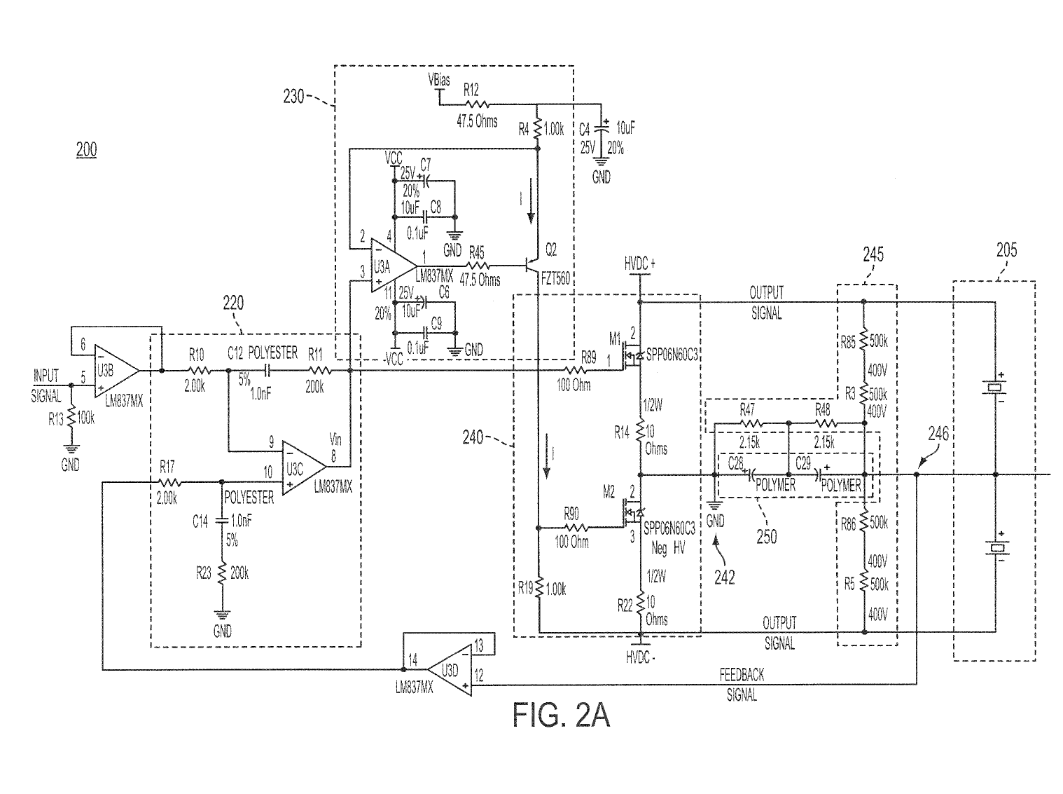

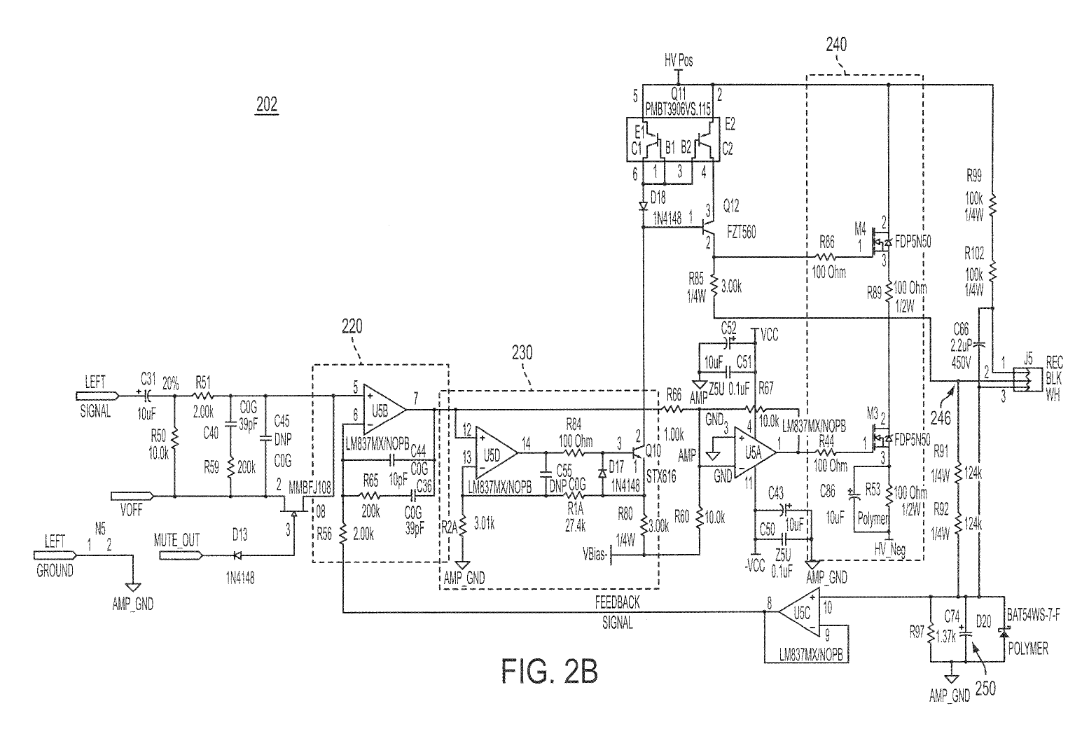

Attention is directed to FIG. 2A that illustrates an example of a system 200 to generate electrical signals for a loudspeaker consistent with the present disclosure. The system may include an error amplifier circuit 220, a voltage to current converter 230, an output stage 240 and a charge sensing circuit 250. The system may include a voltage divider circuit 245 and is configured to drive one or more piezoelectric actuator(s) 205.

The error amplifier circuit 220 is configured to provide an output signal to the voltage-to-current converter 230 and the output stage 240 based, at least in part, on an input signal and a feedback signal, as described herein with respect to FIGS. 1A and 1B. The output stage 240 includes two transistors M1, M2. The transistors M1, M2 are coupled to each other at a node 242. The node 242 may be grounded. The output stage 240 is coupled between a positive high voltage terminal HVDC+ and a negative high voltage terminal HVDC−. The high voltage may be supplied by a power supply, as described herein.

The power supply is configured to provide a DC piezoelectric bias voltage to the piezoelectric actuator(s) 205 via terminals HVDC+ and HVDC−. The transistors M1 and M2 are configured to modulate the voltages on terminals HVDC+ and/or HVDC−, based at least in part, on the output of the error amplifier 220 and/or the voltage to current converter 230. In other words, the piezoelectric actuators 205 may be supplied both DC piezoelectric bias voltages (e.g., configured to prevent depolarization) and AC voltages (e.g., based at least in part on the Input signal) via terminals HVDC+ and/or HVDC−. For example, when the input signal is near zero (i.e., quiescent), a potential between HVDC+ and node 242 may be about +200 VDC and a potential between the HVDC− and node 242 may be about −200 VDC, corresponding to an HVDC output voltage of the power supply of about 400 VDC. In another example, when the input signal is varying between a maximum and a minimum, corresponding to an AC voltage at the output of the output stage of e.g., +/−200 V peak to peak, HVDC+ may vary between zero and 400 V and HVDC− may vary between zero and −400 V. In this manner, each piezoelectric transducer may not receive a depolarizing potential and M1 and M2 may be controlled to vary the potentials on terminal HVDC+ and HVDC− to provide output signal(s) to the piezoelectric actuators 205.

The voltage to current converter 230 is configured to generate an output current, I. The output current, I, may be based, at least in part, on the transistor bias voltage VBias and the output, Vin, of the error amplifier circuit 220. For example, the current I may equal the difference between Vin and VBias, divided by a resistor R4, i.e., I=(Vin-VBias)/R4. Transistor M2 may then be controlled based on the current, I. The current, I, may then be multiplied by resistor R19 to generate a drive (i.e., control) voltage to M2. In other words, transistor M2, that is coupled between HVDC− and node 242 (e.g., ground), may be controlled by a circuit (voltage-to-current converter 230) supplied by typical supply voltages, e.g., +/−VCC=+/−15 V. Advantageously, the voltage to current converter 230 may include an operational amplifier (e.g., operational amplifier U3A) and a transistor (e.g., transistor Q2) in a feedback path. The operational amplifier may have a relatively high open loop gain, as will be understood by one skilled in the art. The current output of the voltage to current converter may be a relatively low distortion representation of the input voltage (e.g., Vin) because of the high open loop gain of the operational amplifier. The voltage to current converter 230 is configured to drive a portion (i.e., transistor M1) of the output stage 240 that is referenced to a voltage (i.e., HVDC−) whose absolute value is greater than a supply voltage (e.g., +/−15 V) to the error amplifier circuit 220.

The DC voltage divider circuit 245 is configured to provide DC feedback to the error amplifier 220 creating quiescent DC voltages of +200V at HVDC+ and −200V at HVDC−. In this manner, a quiescent voltage of zero volts may be maintained at node 246, corresponding to, e.g., HVDC+ equal to about +200V and HVDC− equal to about −200V. In addition to the output signal, the HVDC+ and HVDC− provide HV piezoelectric bias voltage to the piezoelectric actuator(s) 205, to prevent depolarization, as described herein.

The charge sense circuit 250 may include charge sense capacitors C28 and C29. Values of the charge sense capacitors may be based, at least in part, on the specific piezoelectric actuators. The capacitors C28 and C29 may form an AC capacitive divider with the piezoelectric actuators 205, configured to sense a portion of a charge provided to the piezoelectric actuators 205. The charge sense capacitors C28 and C29 may have relatively low voltage coefficients, i.e., their capacitances may vary little with variations in voltage. The charge sense capacitors C28 and C29 may have low effective series resistance, as will be understood by one skilled in the art. The charge sense circuit 250 may be connected to node 242, i.e., ground.

Accordingly, for the example illustrated in FIG. 2A, the piezoelectric actuator(s) 205 may be supplied both DC piezoelectric bias voltages and an AC signal corresponding to the input signal (Input Signal). The charge of the piezoelectric actuators 205 may then be sensed and a feedback signal representative of the sensed charge may be fed back to the error amplifier circuit 220. The feedback signal may include a DC component configured to maintain a DC quiescent voltage at node 246 of about zero volts.

FIG. 2B illustrates another example of a system 202 to generate electrical signals for a loudspeaker consistent with the present disclosure. The system 202 includes an error amplifier circuit 220, a voltage to current converter 230, an output stage 240 and a current sensing circuit 250. Unlike system 200, the transistors (M3, M4) in the output stage are not connected to a ground node. Similar to system 200, the system 202 is configured to provide DC piezoelectric bias voltage and AC signal to the piezoelectric actuators. Further, system 202 is configured to sense the charge on the piezoelectric actuators and feed back a signal representative of the charge to the error amplifier circuit 220. The error amplifier circuit 220 may then cause the system 202 to adjust the output signal to the piezoelectric actuators based, at least in part, on the input signal and the feedback signal.

In system 202, an output signal may be provided to a common terminal of piezoelectric transducers via pin 2 of J5, coupled to node 246, unlike system 200 where terminals HVDC+ and HVDC− provide the output signal(s) to the piezoelectric transducers. In system 202, transistor M3 and may be referenced to ground. In other words, node HV_Neg may be connected to AMP_GND in system 202. HV_Pos may then be coupled to a positive output of a power supply, e.g., may be coupled to +400 V. In this configurations HV_Neg and HV_Pos may not be modulated by transistors M3 and M4 of the output stage 240. As may be appreciated, in this configuration, the output may be biased at 200 V (i.e., one half of 400V), a quiescent point. R97, R91 and R92 may provide a voltage divider configured to provide a DC portion of a feedback signal to error amplifier 220. The error amplifier 220 may be configured to receive an input offset voltage VOFF that may be used to set the quiescent point. The error amplifier 220 is configured to adjust an output based, at least in part, on the offset voltage VOFF and the DC feedback signal. The offset voltage may be proportional to HV_Pos.

In system 202, the charge sensing circuit 250 may include capacitor C74. The value of the capacitor C74 may be based, at least in part, on the piezoelectric actuator(s) coupled to node 246. A first piezoelectric actuator may be coupled between pins 1 and 2 of connector J5 and a second piezoelectric actuator may be coupled between pins 2 and 3 of connector J5. The charge sensing circuit 250 is configured to sense a charge provided to the first and second piezoelectric actuators. In this system 202, capacitor C66 is configured to provide a path for charge so that the charge associated with the first piezoelectric actuator may be sensed by capacitor C74.

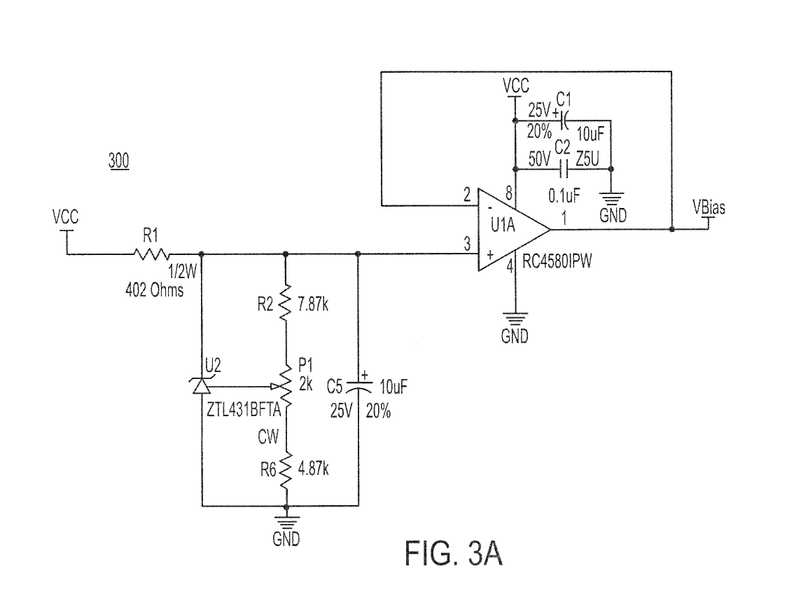

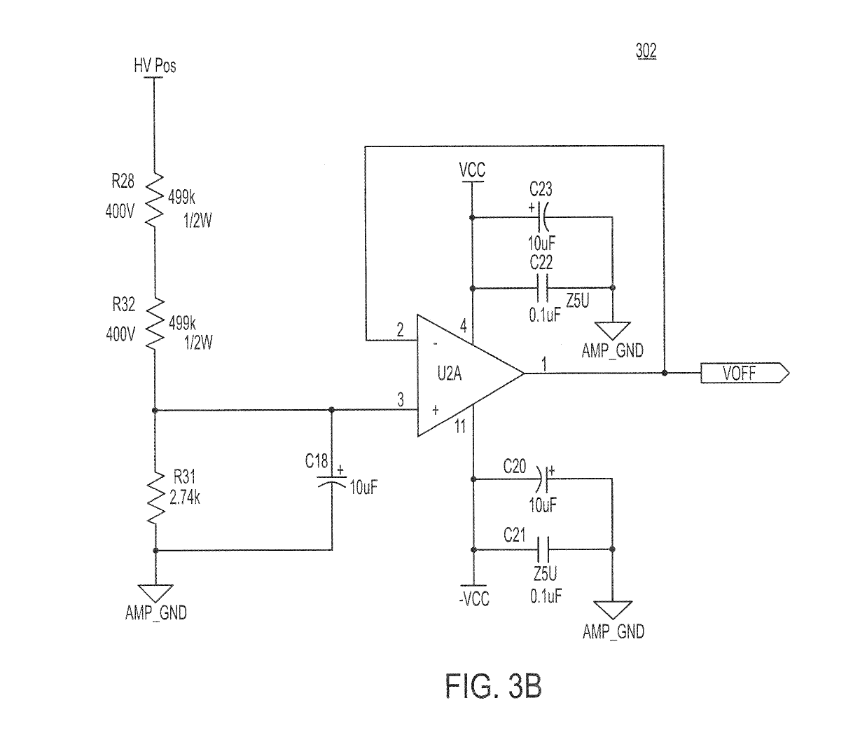

FIG. 3A is an example of a circuit 300 for generating VBias. For example, circuit 300 may be used to provide a positive VBias. The circuit 300 is configured to receive a voltage, e.g., VCC, from a DC supply and/or a power supply, e.g., power supply 160. The circuit 300 may be adjustable, i.e., may be configured to provide an adjustable output, VBias. The circuit 300 is further configured to be temperature stable, as will be understood by one skilled in the art. If a negative bias voltage, VBias−, is desired, node VCC may instead be connected to ground, and node GND may be connected to −VCC. For example, the system of FIG. 2B (i.e., system 202) may utilize a negative bias voltage, VBias−. FIG. 3B is an example of a circuit 302 for generating VOFF, as may be utilized by system 202, as described herein.

Accordingly, a system consistent with the present disclosure, is configured to receive an input signal that may be an audio frequency signal and to provide an output signal to drive one or more piezoelectric actuators, in proportion to the input signal. The system is configured to sense a charge associated with the piezoelectric actuators and to provide a feedback signal, based at least in part, on the sensed charge. The feedback a signal may include a DC portion and an AC portion. The DC portion is configured to set a quiescent operating point for the piezoelectric actuators. The AC portion is configured to represent a portion of the charge provided to the piezoelectric actuators. The system is configured to adjust the output signal based at least in part on the input signal and the feedback signal. The system is configured to generate a relatively high piezoelectric bias voltage, e.g., in the range of about 100 VDC (Volts DC) to about 600 VDC, and a relatively high piezoelectric AC voltage, e.g., in the range of about 200 V peak to peak to about 1200 V peak to peak, for driving the piezoelectric actuator(s). Advantageously, the piezoelectric bias voltage may be supplied to the piezoelectric actuators by a system consistent with the present disclosure, without additional external circuitry. It may now be noted that the system for driving a piezoelectric actuator herein may be specifically utilized in connection an actuator coupled to an edge of a diaphragm for conversion of mechanical energy into acoustical energy. In accordance with such application, the acoustic transducer that employs such piezoelectric actuator that converts a mechanical motion into acoustical energy may comprise the acoustic transducer reported in U.S. Pat. No. 7,038,356 whose teachings are incorporated by reference. The diaphragm may therefore be curved and contain at least one support on at least one portion of the diaphragm and at least one actuator operatively coupled to the diaphragm and spaced from the support. The actuator may then be configured to move such that movement of the actuator produces corresponding movement of the diaphragm, the diaphragm movement being amplified with respect to the actuator movement. The diaphragm may preferably be made of a sheet of optically clear material.

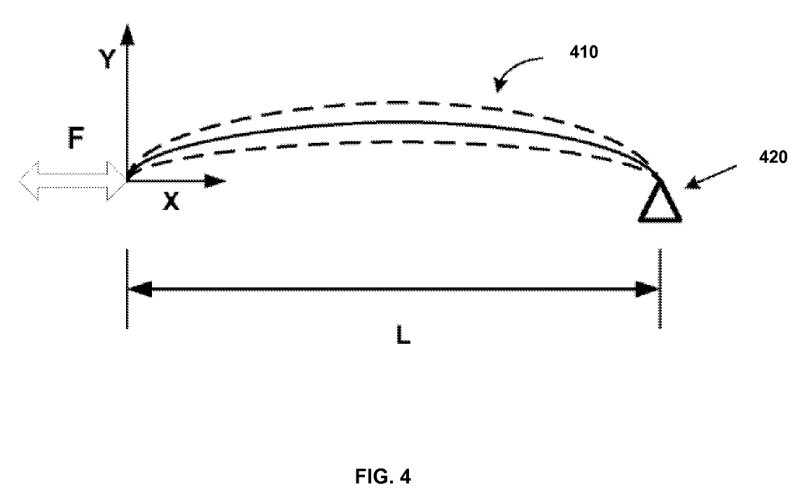

FIG. 4 is an exemplary cross-sectional view illustrating flexure of a diaphragm by application of lateral force F providing lateral motion (“X” axis) and corresponding excursions (“Y” axis). More specifically, the diaphragm 410, which may be biased initially in a curved position, may provide a mechanical disadvantage, allowing relatively small motions (“X” axis) to create a relatively large excursion (“Y” axis). When a force F is applied in alternative directions as shown, by, e.g., a piezoelectric actuator, the diaphragm may vibrate up and down, in piston-like fashion, and may then produce sound. It may also be appreciated that the smaller the curvature of the diaphragm, the greater the mechanical disadvantage. That is higher force may be required, small “X” travel required and greater “Y” motion may be obtained. It may therefore be appreciated that where space can be an issue (e.g. audio in front of a visual display), a high mechanical disadvantage may be useful since it may be desirable to have the diaphragm as flat as possible in a resting position. This may also be useful from the perspective of minimizing optical distortion and reducing aberrant reflections. In FIG. 4, a support is shown generally at 420.

The acoustic transducer herein may also be described as one that converts a mechanical motion into acoustical energy, the acoustic transducer comprising: a diaphragm that is curved; at least one support on at least one portion of the diaphragm; and at least one actuator operatively coupled to the diaphragm and spaced from the support, the actuator configured to move such that movement of the actuator produces corresponding movement of the diaphragm, the diaphragm movement being amplified with respect to the actuator movement, further comprising a seal at at least a portion of the periphery of the diaphragm to assist in maintaining the acoustic pressure gradient across the transducer.

The acoustic transducer may also be described as one that converts a mechanical motion into acoustical energy, the acoustic transducer comprising: a diaphragm that is curved; at least one support on at least one portion of the diaphragm; and at least one actuator operatively coupled to the diaphragm and spaced from the support, the actuator configured to move such that movement of the actuator produces corresponding movement of the diaphragm, the diaphragm movement being amplified with respect to the actuator movement, wherein the support overlies a video screen display and the diaphragm is spaced from the screen display.

“Circuitry”, as used in any embodiment herein, may comprise, for example, singly or in any combination, hardwired circuitry, programmable circuitry, state machine circuitry, and/or firmware that stores instructions executed by programmable circuitry.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents.

Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

What is claimed is:

1. An apparatus for use with an acoustic transducer including a piezoelectric actuator, said apparatus comprising:
an error amplifier circuit configured to receive an input signal and a feedback signal and to provide an output based at least in part on said input signal and said feedback signal wherein said input signal is an audio frequency signal;
an output stage coupled to said error amplifier circuit, said output stage configured to receive said output from said error amplifier circuit and to generate an output signal, based at least in part on said output from said error amplifier circuit wherein said output signal is configured to drive said piezoelectric actuator; and
a charge sensing circuit configured to sense a charge associated with said piezoelectric actuator, wherein said feedback signal is based, at least in part, on said sensed charge.

2. The apparatus of claim 1, further comprising a voltage to current converter configured to receive said output from said error amplifier circuit and to provide a current output to said output stage, wherein said voltage to current converter is configured to drive a portion of said output stage that is referenced to a voltage whose absolute value is greater than a voltage supplied to said error amplifier circuit.

3. The apparatus of claim 2, wherein said voltage to current converter comprises an operational amplifier and a transistor coupled in a feedback loop of said operational amplifier.

4. The apparatus of claim 1, wherein the charge sensing circuit comprises at least one capacitor and a voltage across said capacitor represents said charge associated with said piezoelectric actuator.

5. The apparatus of claim 1, wherein said apparatus is configured to provide a piezoelectric bias voltage to said piezoelectric actuator, wherein said piezoelectric bias voltage is provided from one or more high voltage terminals coupled to said output stage and said piezoelectric bias voltage is configured to prevent depolarizing said piezoelectric actuator.

6. The apparatus of claim 5, wherein said output signal comprises said piezoelectric bias voltage.

7. The apparatus of claim 1, wherein said audio frequency signal comprises content in a frequency range of 20 Hz to 20,000 Hz.

8. An acoustic transducer that converts a mechanical motion into acoustical energy, said acoustic transducer comprising:
a diaphragm that is curved;
at least one support on at least one portion of said diaphragm;
at least one piezoelectric actuator operatively coupled to said diaphragm and spaced from said support, said actuator configured to move such that movement of said actuator produces corresponding movement of said diaphragm, said diaphragm movement being amplified with respect to said actuator movement;
an error amplifier circuit configured to receive an input signal and a feedback signal and to provide an output based at least in part on said input signal and said feedback signal wherein said input signal is an audio frequency signal;
an output stage coupled to said error amplifier circuit, said output stage configured to receive said output from said error amplifier circuit and to generate an output signal, based at least in part on said output from said error amplifier circuit wherein said output signal is configured to drive said piezoelectric actuator; and
a charge sensing circuit configured to sense a charge associated with said piezoelectric actuator, wherein said feedback signal is based, at least in part, on said sensed charge.

9. The acoustic transducer of claim 8, further comprising a voltage to current converter configured to receive said output from said error amplifier circuit and to provide a current output to said output stage, wherein said voltage to current converter is configured to drive a portion of said output stage that is referenced to a voltage whose absolute value is greater than a voltage supplied to said error amplifier circuit.

10. The acoustic transducer of claim 9, wherein said voltage to current converter comprises an operational amplifier and a transistor coupled in a feedback loop of said operational amplifier.

11. The acoustic transducer of claim 8, wherein the charge sensing circuit comprises at least one capacitor and a voltage across said capacitor represents said charge associated with said piezoelectric actuator.

12. The acoustic transducer of claim 8, wherein said acoustic transducer is configured to provide a piezoelectric bias voltage to said piezoelectric actuator, wherein said piezoelectric bias voltage is provided from one or more high voltage terminals coupled to said output stage and said piezoelectric bias voltage is configured to prevent depolarizing said piezoelectric actuator.

13. The acoustic transducer of claim 12, wherein said output signal comprises said piezoelectric bias voltage.

14. The apparatus of claim 8, wherein said audio frequency signal comprises content in a frequency range of 20 Hz to 20,000 Hz.

15. A system comprising:
an acoustic transducer comprising a piezoelectric actuator; and
an apparatus for driving said piezoelectric actuator, said apparatus comprising:
an error amplifier circuit configured to receive an input signal and a feedback signal and to provide an output based at least in part on said input signal and said feedback signal wherein said input signal is an audio frequency signal;
an output stage coupled to said error amplifier circuit, said output stage configured to receive said output from said error amplifier circuit and to generate an output signal, based at least in part on said output from said error amplifier circuit wherein said output signal is configured to drive said piezoelectric actuator; and
a charge sensing circuit configured to sense a charge associated with said piezoelectric actuator, wherein said feedback signal is based, at least in part, on said sensed charge.

16. The system of claim 15, further comprising a voltage to current converter configured to receive said output from said error amplifier circuit and to provide a current output to said output stage, wherein said voltage to current converter is configured to drive a portion of said output stage that is referenced to a voltage whose absolute value is greater than a voltage supplied to said error amplifier circuit.

17. The system of claim 16, wherein said voltage to current converter comprises an operational amplifier and a transistor coupled in a feedback loop of said operational amplifier.

18. The system of claim 15, wherein the charge sensing circuit comprises at least one capacitor and a voltage across said capacitor represents said charge associated with said piezoelectric actuator.

19. The system of claim 15, wherein said apparatus is configured to provide a piezoelectric bias voltage to said piezoelectric actuator, wherein said piezoelectric bias voltage is provided from one or more high voltage terminals coupled to said output stage and said piezoelectric bias voltage is configured to prevent depolarizing said piezoelectric actuator.

20. The system of claim 19, wherein said output signal comprises said piezoelectric bias voltage.

21. The apparatus of claim 15, wherein said audio frequency signal comprises content in a frequency range of 20 Hz to 20,000 Hz.
